(19) United States
(12) Patent Application Publication
(10) Pub. No.: US 2007/0057834 A1
(43) Pub. Date: Mar. 15, 2007

(54) Method and system for obtaining enhanced signal to noise ratio in a laser imaging apparatus

(76) Inventor: Robert H. Wake, Cooper City, FL (US)

Correspondence Address: SHLESINGER, AKRWRIGHT & GARVEY LLP, Suite 600, 1420 King Street, Alexandria, VA, 22314, US

(21) Appl. No.: 11/512,246

(22) Filed: Aug. 30, 2006

Related U.S. Application Data
(60) Provisional application No. 60/716,971, filed on Sep. 15, 2005.

(51) Int. Cl. H03M 1/12

(52) U.S. Cl. 341/155

(57) ABSTRACT

A method for measuring a small, low-frequency electrical current, comprising integrating the electrical current with an operational amplifier configured as a switched integrator to provide an output; digitizing the output of the integrator multiple times to obtain an array of measured values; and calculating a slope of the integrator output by fitting a least squares curve to the array of measured values, wherein the electrical current is proportional to the slope. A system for measuring a small, low-frequency electrical current, comprises an operational amplifier configured as a switched integrator connected to a source of the small, low-frequency electrical current; an analog-to-digital converter connected to the output of the switched integrator; a controller connected to the ADC for digitizing the output of the integrator multiple times to obtain an array of measured values; and a computer for calculating a slope of the integrator output by fitting a least squares curve to the array of measured values, wherein the electrical current is proportional to the slope.

### RELATED APPLICATION

This is a nonprovisional application claiming the priority benefit of provisional application Ser. No. 60/716,971, filed Sep. 15, 2005, hereby incorporated by reference.

### FIELD OF THE INVENTION

The present invention relates generally to a method and system for measuring very small electrical current, and specifically to improving the accuracy of data obtained in a laser imaging apparatus.

### BACKGROUND OF THE INVENTION

The dynamic range of light levels in an optical tomographic scanner is very large, as high as 10⁷:1. The typical optical scanner geometry is illustrated in FIG. 1, where a light source 2, typically a near-infrared laser, illuminates the scanned object 4, typically a breast. A ring of detectors 6 views the scanned object, each detector seeing light that is transmitted through a portion of the breast and re-emitted. For several detectors, the light paths 8, 10 and 12 are shown.

The light levels are generally quite low and vary with detector position and scanned object size and composition. Between detector 14 and detector 16, the light level differs by a factor of 10³ to 10⁵. This is due to light absorption within the scanned object and the difference in path lengths 10 and 8. The light transmission is given by:
I=I₀e⁻^{^{μ}}^{x}
where I is the detected intensity, I₀ is the incident intensity, μ is the effective linear attenuation coefficient of the medium and x is the path length in the medium. The ratios of intensities detected by detectors 14 and 16 is given by:
R=e⁻^{^{μ}}^{(x}^{₁₆}^{-x}^{₁₄}⁾
where R is the ratio of intensities, x₁₆ is the path length in the medium for detector 14 and x₁₆ is the path length in the medium for detector 16. For a μ of 1.0 cm⁻¹, which is a typical value for tissue and path lengths of 10=4 cm and light path 8=15 cm, the intensity ratio between these detectors is 60,000:1.

Different scanned objects, different breasts can exhibit attenuation values ranging 10:1 or greater. Changing the position of the breast within the scanning mechanism will further exacerbate the dynamic range problem. The net effect is that the detectors are required to measure light intensities over a range of 10⁷:1 in the absolute worst case.

The most suitable photodetector for this application is a silicon photodiode. Photodiodes exhibit small physical size and insensitivity to acceleration and magnetic fields, unlike photomultiplier tubes. Photodiode's quantum efficiency is far better than photomultiplier's at the 800 nm near-infrared wavelength of biological interest. They are available with extremely small leakage currents for photoconductive application and high shunt resistances for photovoltaic application. In the scanning application, the photodiode photocurrents may be as low as a few picoamps (10⁻¹² Amps) to as high as tens of microamps.

U.S. Pat. Nos. 6,150,649 and 6,331,700 disclose the use of integrating amplifiers with variable integration times as a partial solution to this dynamic range problem. Referring to FIG. 3, the photodiode 18 photocurrent is integrated by a switched integrator 20 whose integration time is varied to accommodate the dynamic range. The photocurrent from photodiode 18 is impressed on the inverting input of operational amplifier 20 if FET switch 22, the “HOLD” switch is closed. If FET switch 24, the “RESET” switch is open, the output 26 of amplifier 20 ramps negative, charging capacitor 28 at a rate given by:

$$V = \frac{i * t}{C}$$

where V is the output voltage, I is the photocurrent, t is the time that the photocurrent has been charging capacitor 28 and C is the value of capacitor 28. Thus the circuit gain (volts out per amperes in) can be set by changing the capacitor or by changing the integration time.

U.S. Pat. No. 6,681,130 discloses the use of oversampling, repeated digitizations of the same signal, to improve the signal-to-noise of the measured optical signals. It is well known that averaging multiple samples of a signal with additive (presumably Gaussian) noise will reduce the noise by the square root of the number of samples. The disadvantage of this method is that it lengthens the digitization dead time, thereby lengthening the total time to acquire a given amount of data.

Neither of these approaches address a limitation of the switched integrator. FIG. 4 illustrates the ideal behavior of the switched integrator. During the RESET period, the output voltage will be nominally 0 Volts. During the INTEGRATE period, the output will ramp linearly downward. During the DIGITIZE period, the output will remain at the final ramp value for digitization. This is the ideal behavior of the switched integrator.

The actual behavior is more complex. Referring to FIG. 3, parasitic capacitors 30 and 32 inject charge from the HOLD* and RESET signals, respectively, into the analog circuit. This produces offsets in the analog output of the integrator, as well as some uncertainty or noise in these offsets caused by noise on the digital HOLD* and RESET signals. FIG. 5 illustrates this effect, over a number of repetitions of the integration-digitization-reset sequence.

At point 34, the RESET switch 24 (see FIG. 3) opens, introducing a charge-injection offset into the output, shown by the multiple ramping signals. Noise on the RESET signal causes an uncertainty in the starting point of these ramps, though the slope remains constant. At point 36, the HOLD switch 22 (see FIG. 3) opens and the signal can now be digitized. Another charge-injection error is introduced in the level of the signal by noise on the HOLD* signal, increasing the digitized error. With a 100 pF integration capacitor, the total charge-injection error is typically several hundred microvolts.

The feedthrough capacitances are quite small, on the order of picofarads. But the integration capacitor in the preferred embodiment is 100 picofarads, in order to make a measurable signal from a very small photocurrent. A gain stage can be inserted between the amplifier 20 and ADC 38 to increase the level of signals from small photocurrents. For example, a 1 picoampere photocurrent integrated for 10 milliseconds with a 100 picofarad integration capacitor will produce a 100 microvolt output signal. Even with a 16-bit ADC, assuming a 10 volt full scale input range, this will be a 0.6 ADC-count signal. The ADC quantization noise will dominate. With a gain of 100 between the amplifier and ADC, the signal will be 65 ADC counts. However, the charge-injection noise will also be amplified by the gain of 100 and will likely limit the signal to noise.

### OBJECTS AND SUMMARY OF THE INVENTION

It is an object of the present invention to provide a method and system for measuring light levels over a large dynamic range with enhanced signal-to-noise ratio, using a photodiode, a switched integrator and an analog-to-digital converter.

It is another object of the present invention to provide a method and system for measuring light levels over a large dynamic range with enhanced signal-to-noise ratio, using a photodiode, switched integrator and an analog-to-digital converter, where the slope of the output of the integrator is fitted to a curve, such as a linear equation, to obtain the value of the slope, which is proportional to the measured light

It is another object of the present invention to provide a method and system for measuring light levels over a large dynamic range with enhanced signal-to-noise ratio, using a photodiode, switched integrator and an analog-to-digital converter, level, where the effect of charge injection in the switched integrator on the measurement is minimized.

It is an object of the present invention to provide a method and system for measuring light levels over a large dynamic range with enhanced signal-to-noise ratio, using a photodiode, switched integrator and an analog-to-digital converter, where the effect of ADC quantization error on the measurement is minimized.

It is another object of the present invention to provide a method and system for measuring light levels over a large dynamic range with enhanced signal-to-noise ratio, using a photodiode, switched integrator and an analog-to-digital converter, where the effect of additive noise on the measurement is minimized.

It is still another object of the present invention to provide a method and system for measuring light levels over a large dynamic range with enhanced signal-to-noise ratio, using a photodiode, switched integrator and an analog-to-digital converter, where the volume of data required to calculate the least squares curve fit is reduced by performing certain summations of the data are performed prior to curve fitting.

In summary, the present invention provides a method for measuring a small, low-frequency electrical current, comprising integrating the electrical current with an operational amplifier configured as a switched integrator to provide an output; digitizing the output of the integrator multiple times to obtain an array of measured values; and calculating a slope of the integrator output by fitting a least squares curve to the array of measured values, wherein the electrical current is proportional to the slope.

The present invention also provides a system for measuring a small, low-frequency electrical current, comprising an operational amplifier configured as a switched integrator connected to a source of the small, low-frequency electrical current; an analog-to-digital converter connected to the output of the switched integrator; a controller connected to the ADC for digitizing the output of the integrator multiple times to obtain an array of measured values; and a computer for calculating a slope of the integrator output by fitting a least squares curve to the array of measured values, wherein the electrical current is proportional to the slope.

These and other objects of the present invention will become apparent from the following detailed description.

### BRIEF DESCRIPTIONS OF THE DRAWINGS

FIG. 1 is a schematic side elevational view of a laser imaging apparatus with a patient in a prone position with one of her breasts positioned within a scanner for an optical tomographic study.

FIG. 2 is a schematic diagram of an optical scanner showing the breast disposed within an arc of detectors.

FIG. 3 is a schematic block diagram of a signal processing circuit for an optical detector using a switched integrator.

FIG. 4 is a timing diagram of an ideal switched integrator of FIG. 3.

FIG. 5 is a timing diagram of a switched integrator of FIG. 3 showing the offsets introduced by charge injection

FIG. 6 is a schematic block diagram of a signal processing circuit made in accordance with the present invention for an optical detector using a switched integrator and accumulating the values to fit a least-squares linear curve.

FIG. 7 is a timing diagram of a switched integrator and ADC of FIG. 6.

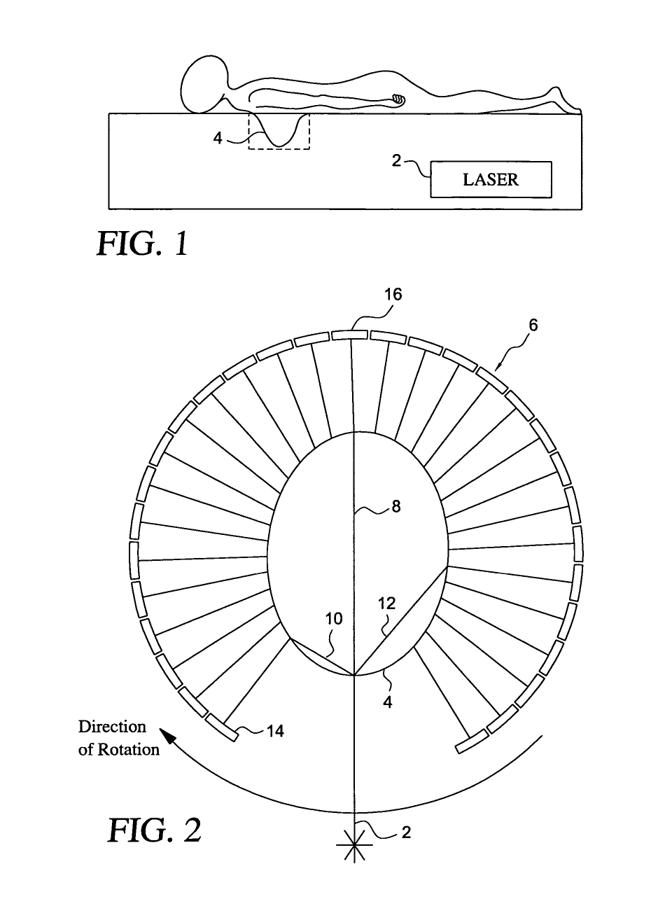

### DETAILED DESCRIPTION OF THE INVENTION

The present invention provides a method and system for measuring a signal with a very large dynamic range while accommodating both ADC quantization error and integrator charge-injection error. The present invention measures the slope of the integrator output and ignores the intercept. The slope is proportional to the photocurrent, while the intercept is dominated by the charge-injection error. The present invention digitizes the integrator output continuously and then performs a least-squares linear fit to the output data and calculates the slope from the curve fit.

Least-squares linear curve fitting is a well known statistical technique to extract the slope and intercept of the linear equation that best fits the experimental data, by minimizing the sum of the least-squared error between the measure and calculated points. The linear curve is expressed as:
y=m*x+b,
where: y is the measured value,
x is the index,
m is the slope of the linear curve, and
b is the intercept of the linear curve, the y value at x=0.

As a “C” language program, the following program calculates the least-squares fit to an array of measured data points, sampled at equal spacing (equal time spacing in the optical system). The array of measured values, meas[] is n_sam samples long.

int i, n_sam, meas[n_sam];
double x, y, sx, sy, sxsq, sysq, sxy, m, b;
for (i=0, sx=0.0, sy=0.0, sxsq=0.0, sysq=0.0, sxy=0.0; i < n_sam; i++)

| { | |
|---|---|
| x = (double) i; | /* index */ |
| y = (double) meas[i]; | /* measured value */ |
| sx += x; | /* sum indices */ |
| sy += y; | /* sum measurements */ |
| sxsq += x * x; | /* sum indices² */ |
| sysq += y * y; | /* sum measurements² */ |

| | |
|---|---|
| sxy += x * y; | /* sum measurements * indices */ |
| } | |

m = ((n_sam * sxy) − (sx * sy))/((n_sam * sxsq) − (sx * sx));
b = ((sy * sxsq) − (sx * sxy))/((n_sam * sxsq) − (sx * sx));

The switched integrator could saturate if the photocurrent were sufficiently high. At a 10 microamp photocurrent, a switched integrator with a 100 pF feedback capacitor will reach 10 Volts, saturation, in 100 microseconds. If the total measurement were longer than 100 microseconds, the calculation of slope would have to only employ the measured points prior to saturation. The following “C” program includes a test comparing the measured value to some maximum allowed measurement value:

int i, n_sam, meas[n_sam], act_sam, max_meas;
double x, y, sx, sy, sxsq, sysq, sxy, m, b;
for (i=0, sx=0.0, sy=0.0, sxsq=0.0, sysq=0.0, sxy=0.0; i < n_sam; i++)

| { | |
|---|---|
| x = (double) i; | /* index */ |
| y = (double) meas[i]; | /* measured value */ |

if (meas[i] > max_meas)

{
break;
}

| act_sam = i + 1; | |
|---|---|
| sx += x; | /* sum indices */ |
| sy += y; | /* sum measurements */ |
| sxsq += x * x; | /* sum indices² */ |
| sysq += y * y; | /* sum measurements² */ |

| | |
|---|---|
| sxy += x * y; | /* sum measurements * indices */ |
| } | |

m = ((act_sam * sxy) − (sx * sy))/((act_sam * sxsq) − (sx * sx));
b = ((sy * sxsq) − (sx * sxy))/((act_sam * sxsq) − (sx * sx));

It is only necessary to calculate the slope m of the linear curve, not its intercept b, for measuring the photocurrent. Thus, the sxy, sx, sy and sxsq must be calculated, along with act_sam. But sx and sxsq can be calculated, or looked-up, from act_sam. Thus only three values must be calculated to compute the slope m: sy, sxy and act_sam.

The least squares curve fit is advantageously robust with respect to noise. Like the oversampling disclosed in U.S. Pat. No. 6,681,130, the multiple digitizations of the ramp have an averaging effect on additive noise. And the digitization of the ramp adds no dead time, unlike the oversampling disclosed in U.S. Pat. No. 6,681,130. In the preferred embodiment, the ramp will be digitized at 100 KHz for a 10 millisecond integration time. The 1000 samples will reduce any additive noise by approximately 16×. By comparison, the 29× oversampling of the preferred embodiment disclosed in U.S. Pat. No. 6,681,130 reduces the additive noise by approximately 5×.

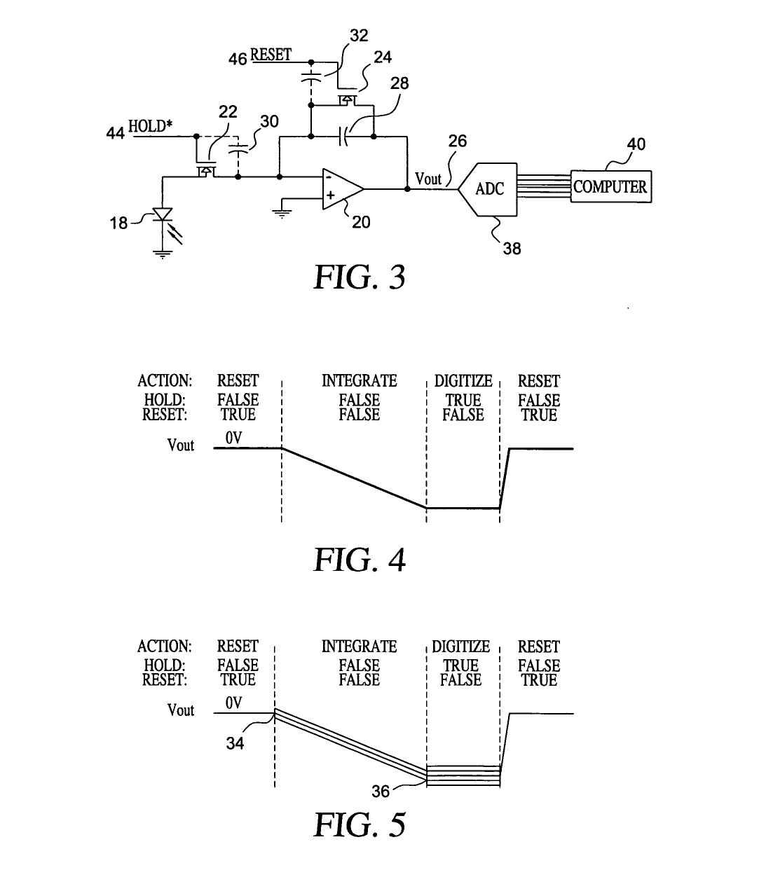

These calculations could be performed by a general-purpose computer 40 (see FIG. 3), passing all the measured data to the computer for subsequent processing. But the volume of data would be excessive. There could be several hundred channels of detector electronics, 192 channels in the preferred embodiment, with an ADC digitization rate of 100 KHz or more. The total data rate exceeds 3 G bits/second.

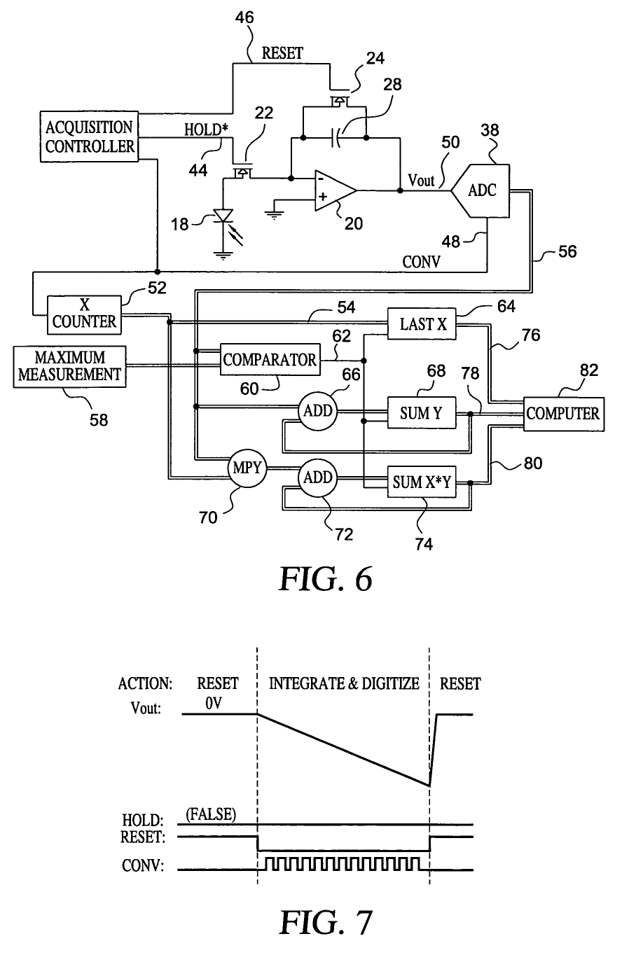

To advantageously reduce the amount of data to be sent to the computer 40, the present invention in the preferred embodiment calculates the three terms (sx, sxy and act_sam) for each detector in a programmable gate array. The logic of the calculation is illustrated in FIG. 6. Done this way, the hundreds to thousands of samples that are digitized during one integration become three numbers and the bandwidth to transmit these data for the preferred 192 channels becomes on the order of 10M bits/second, a very manageable data rate.

Referring to FIG. 6, an acquisition controller 42 creates the timing for acquiring the optical data. It creates the HOLD* 44 and RESET 46 signals to control the switched integrator and the CONV 48 signal to cause the ADC 38 to digitize the ramp signal Vout 50 from the integrator 20. The CONV signal also clocks a X counter 52 which provides the X index value 54 for each ADC digital output value 56. The ADC output 56 is compared to a maximum measurement value 58 by comparator 60. So long as the ADC output has not exceeded the maximum measurement, the comparator's output 62 will be true, allowing the accumulation of the measured data. The Last X latch 64 will update with the current X index so long as the comparator output is true. Thus, it will contain the index of the last valid measurement point. The measured ADC value 56 is accumulated, summed, by the adder 66 and latch 68, enabled by the comparator decision. The measured ADC value 56 is multiplied by the X index in multiplier 70 and the product is accumulated, summed, by the adder 72 and latch 74, enabled by the comparator decision. The three outputs, Last X 76, Sum Y 78 ands Sum XY 80 are passed to the computer 82. Software running in the computer will calculate the slope m (see the C program) from these three values.

FIG. 7 illustrates the control signals from the acquisition controller 42 along with the integrator output.

While this invention has been described as having preferred design, it is understood that it is capable of further modification, uses and/or adaptations following in general the principle of the invention and including such departures from the present disclosure as come within known or customary practice in the art to which the invention pertains, and as may be applied to the essential features set forth, and fall within the scope of the invention or the limits of the appended claims.

I claim:

1. A method for measuring a small, low-frequency electrical current, comprising:
a) integrating the electrical current with an operational amplifier configured as a switched integrator to provide an output;
b) digitizing the output of the integrator multiple times to obtain an array of measured values; and
c) calculating a slope of the integrator output by fitting a least squares curve to the array of measured values, wherein the electrical current is proportional to the slope.

2. A method as in claim 1, and further including accumulating the array of measured values are accumulated to a smaller number of values prior to said calculating.

3. A method as in claim 2, wherein said accumulating is implemented in a programmable gate array.

4. A method as in claim 1 wherein the measured current is a photocurrent from an optical detector in a laser imaging apparatus.

5. A method as in claim 1 where the measured current is a photocurrent from an optical detector in an X-ray imaging apparatus.

6. A method for measuring small light signals, comprising:
a) impinging the small light signals onto a photodetector to generate an electrical current;
b) inputting the output of the photodetector to an operational amplifier configured as a switched integrator to provide an integrator output;
c) integrating the electrical current with an operational amplifier configured as a switched integrator to provide an output;
d) digitizing the output of the integrator multiple times to obtain an array of measured values; and
e) calculating a slope of the integrator output by fitting a least squares curve to the array of measured values, wherein the electrical current is proportional to the slope.

7. A method as in claim 6, and further including accumulating the array of measured values are accumulated to a smaller number of values prior to said calculating.

8. A method as in claim 7, wherein said accumulating is implemented in a programmable gate array.

9. A method as in claim 6 wherein the photodetector is part of a laser imaging apparatus.

10. A method as in claim 6 where the photodetector is part of an X-ray imaging apparatus.

11. A system for measuring a small, low-frequency electrical current, comprising:
a) an operational amplifier configured as a switched integrator connected to a source of the small, low-frequency electrical current;
b) an analog-to-digital converter (ADC) connected to the output of said switched integrator;
c) a controller connected to said ADC for controlling said ADC for digitizing the output of the integrator multiple times to obtain an array of measured values; and
d) a computer for calculating a slope of the integrator output by fitting a least squares curve to the array of measured values, wherein the electrical current is proportional to the slope.

12. A system for as in claim 11, and further comprising a programmable gate array for reducing the amount of data passed to said computer prior to calculating the slope of the integrator output.
